(19) United States
(12) Patent Application Publication
(10) Pub. No.: US 2026/0114104 A1
(43) Pub. Date: Apr. 23, 2026

(54) DISPLAY DEVICE

(71) Applicant: LG Display Co., Ltd., Seoul (KR)

(72) Inventors: Yeonjae Jeong, Seoul (KR); JaeHyoung Park, Gimpo-si (KR); Giyoun Kim, Goyang-si (KR)

(73) Assignee: LG Display Co., Ltd., Seoul (KR)

(21) Appl. No.: 19/310,549

(22) Filed: Aug. 26, 2025

(30) Foreign Application Priority Data
Oct. 22, 2024 (KR) 10-2024-0144741

(51) Int. Cl. H10H 29/854; H10H 29/49

(52) U.S. Cl. CPC H10H 29/854; H10H 29/49

(57) ABSTRACT

A display device can include a display panel having a pattern layer and a resin film that is flexible and disposed in at least one location below or above the display panel. The pattern layer includes a plurality of first plate patterns spaced apart from each other and in which a sub pixel including a display element and a driving element is disposed, a plurality of first line patterns connecting the plurality of first plate patterns, a plurality of second plate patterns spaced apart from each other and in which a gate driver is disposed, and a plurality of second line patterns connecting the plurality of second plate patterns or connecting the first plate pattern and the second plate pattern. The resin film can be obtained by curing a material including urethane acrylate and two types of photoinitiators.

### CROSS-REFERENCE TO RELATED APPLICATIONS

This application claims priority to Korean Patent Application No. 10-2024-0144741 filed in the Republic of Korea on Oct. 22, 2024, the entire disclosure of which is incorporated by reference into the present application.

### BACKGROUND

### Field

The present disclosure relates to a display device, and more particularly to a stretchable display device which can be stretched.

### Discussion of the Related Art

Among display devices which are used for a monitor of a computer, a television, or a cellular phone, there are an organic light emitting display device (OLED) which is a self-emitting device and a liquid crystal display device (LCD) which requires a separate light source.

An applicable range of the display device can be diversified to personal digital assistants as well as monitors of computers and televisions and a display device with a large display area and a reduced volume and weight is being studied.

Recently, a display device which is manufactured by forming a display unit and a wiring line on a flexible substrate such as plastic being a flexible material, so as to be stretchable in a specific direction and changeable in various forms, is getting attention as a next generation display device.

The stretchable display device which can be stretched needs to have an easily bendable and stretchable property. In that case, a substrate formed with polydimethylsiloxane (PDMS) which has a small modulus to have ductility is used, and an adhesive layer and a cover member having a stretchability matching therewith are also used.

### SUMMARY OF THE DISCLOSURE

When a polydimethylsiloxane (PDMS) substrate is used in a stretchable display device, a silicon-based adhesive layer having a similar stretching characteristic thereto is used. The silicon-based adhesive layer has excellent adhesive property to the PDMS substrate, but due to its high releasing strength, it can be difficult or challenging to form a layer which configures a panel on the adhesive layer. Further, there can be a problem of this layer being peeled off.

Therefore, an acrylic adhesive layer can be used. The acrylic adhesive layer has a releasing strength lower than the silicon-based adhesive layer so that the acrylic adhesive layer can be easy to form the display panel. However, due to the surface characteristic of the PDMS substrate having a low surface energy, there can be a problem or limitation in that the adhesive strength between the PDMS substrate and the acrylic adhesive layer is low, which can cause an interfacial separation and Z-axis deformation of the panel line.

Accordingly, an object to be achieved by the present disclosure is to provide a display device which has an excellent stretching reliability by solving or addressing the interfacial separation problem/limitation due to the difference in the stretching characteristics between the substrate and the adhesive layer.

Another object to be achieved by the present disclosure is to provide a display device which simplifies a structure and has a high stretching characteristic, and an improved manufacturing efficiency.

Objects of the present disclosure are not limited to the above-mentioned objects, and other objects, which are not mentioned above, can be clearly understood by those skilled in the art from the following descriptions.

In order to achieve the above-described objects, according to an aspect of the present disclosure, a display device can include a display panel having a pattern layer and a resin film that is a flexible film and disposed in at least one location below or above the display panel. The pattern layer includes a plurality of first plate patterns which are spaced apart from each other and in which a sub pixel including a display element and a driving element is disposed; a plurality of first line patterns connecting the plurality of first plate patterns; a plurality of second plate patterns which are spaced apart from each other and in which a gate driver is disposed; and a plurality of second line patterns connecting the plurality of second plate patterns or connecting one of the first plate patterns and one of the second plate patterns. The resin film can be obtained by curing a material including urethane acrylate and two types of photoinitiators.

Other detailed matters of the example embodiments of the present disclosure are included in the detailed description and the drawings.

According to the example embodiments of the present disclosure, the display device can include a flexible resin film in at least one of locations: below the display panel, between the display panel and the touch panel, and above the touch panel. The resin film can include urethane acrylate and two types of photoinitiators having different absorption wavelengths. Such a resin film serves as a substrate which supports and protects components disposed above and/or below the resin film and has an adhesive characteristic. Therefore, when the resin film is provided, an adhesive layer for bonding the components disposed above and/or below the resin film can be omitted so that the structure and the manufacturing process of the display device can be simplified.

Further, in a related art, an adhesive layer was used to bond the lower substrate, the upper substrate, and/or the cover member. However, in this case, there was a problem/limitation in that materials which configured the lower substrate, the upper substrate, the cover member, and the adhesive layer had a physical property different from a demanded physical property so that it was necessary to match the stretching characteristic. Further, in a related art, when a substrate formed of a silicon-based elastic material having excellent stretching property and a silicon-based adhesive layer are bonded, the adhesive strength therebetween is excellent, but the releasing strength of the silicon-based adhesive layer is high, so the adhesive strength between the silicon-based adhesive layer and the display panel can become inferior, making it difficult to manufacture a display panel of high quality, and the interfacial separation can occur as a result. In the meantime, in a related art, when the acrylic adhesive layer is bonded onto a substrate formed of a silicon-based elastic material, a surface energy difference between two materials is so large due to the material characteristic of the silicon-based elastic material and the acrylic adhesive layer, which can cause an interfacial separation or the Z-axis deformation of a wiring line which configures a panel.

To address these limitations associated with the related art, according to one or more example embodiments of the present disclosure, a resin film provided in a display device serves as a substrate and has an adhesive characteristic so that there is no need to bond the adhesive layer. Further, the resin film has excellent stretching characteristics and excellent stretching durability and reliability as compared with the substrate bonded with the adhesive layer. Further, the adhesive layer is omitted to reduce the thickness of the display device, thereby reducing a stretching stress and implementing a highly stretchable display device.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an exploded perspective view schematically illustrating a display device according to example embodiments of the present disclosure;

FIG. 2 is a plan view illustrating an example of a display panel included in the display device of FIG. 1;

FIG. 3 is an enlarged plan view illustrating an example of a part A of FIG. 2;

FIG. 4 is a cross-sectional view illustrating an example taken along the line III-III′ of FIG. 3;

FIGS. 5A to 5J are cross-sectional views for explaining a manufacturing method of a display device according to an example embodiment of the present disclosure;

FIG. 6 is a schematic cross-sectional view for explaining another example of a display device according to an embodiment of the present disclosure;

FIG. 7 is a schematic cross-sectional view for explaining still another example of a display device according to an embodiment of the present disclosure; and

FIG. 8 is a schematic cross-sectional view for explaining still another example of a display device according to an embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When described as “connected” or “coupled,” unless the terms “directly” or “immediately” are used, the connection or coupling can include indirect connections or couplings through one or more other components positioned between the two elements.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure. Further, the term “can” fully encompasses all the meanings and coverages of the term “may” and vice versa.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present disclosure will be described in detail with reference to accompanying drawings. All the components of each display device/apparatus according to all embodiments of the present disclosure are operatively coupled and configured.

A display device according to example embodiments of the present disclosure is a display device which is capable of displaying images even in a bent or extended state and can also be referred to as a stretchable display device, a flexible display device and an extendable display device. As compared with the general display devices of the related art, the display device can have not only a high flexibility, but also stretchability. Therefore, the user can bend or extend a display device and a shape of a display device can be freely changed in accordance with manipulation of a user. For example, when the user pulls the display device by holding ends of the display device, the display device can be extended to the pulling direction of the user. Alternatively, when the user disposes the display device on an outer surface which is not flat, the display device can be disposed to be bent in accordance with the shape of the outer surface of the wall. Further, when a force applied by the user is removed, the display device can return to its original shape.

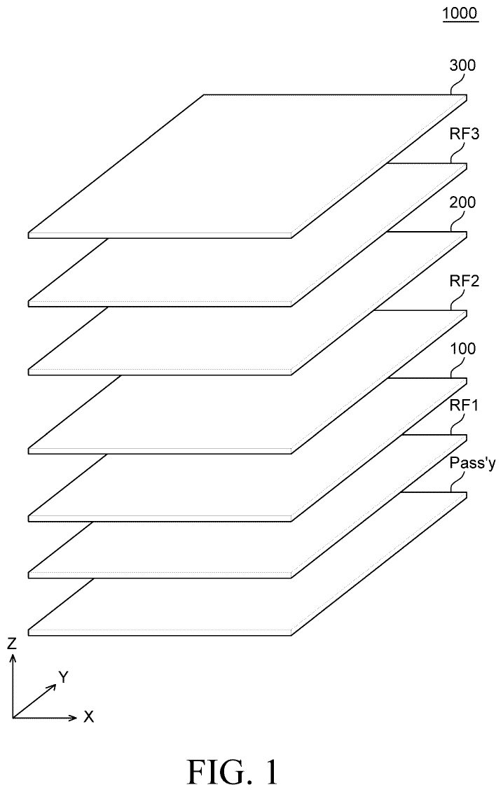

A display device according to one or more example embodiments of the present disclosure will be described with reference to FIGS. 1 to 4 together.

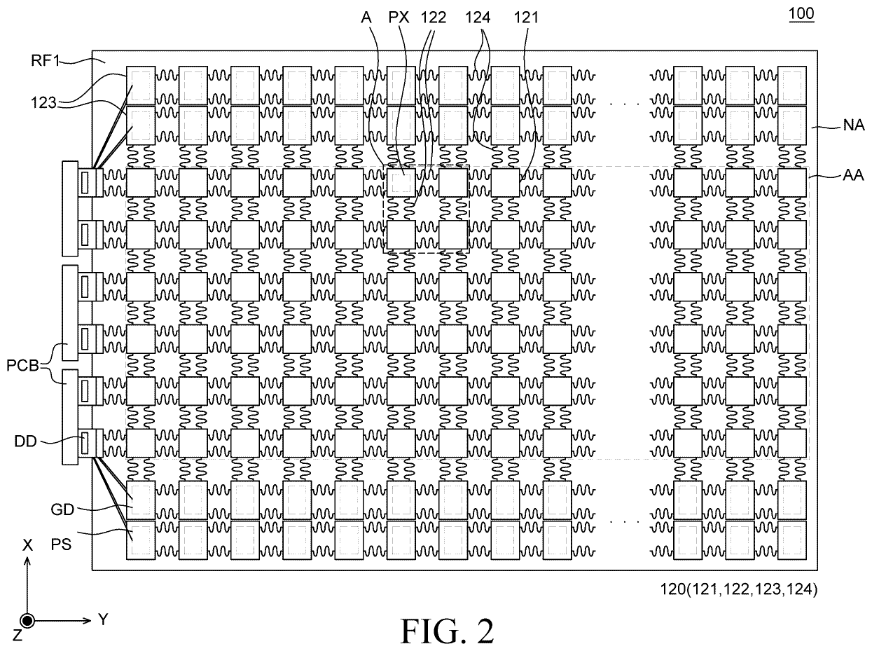

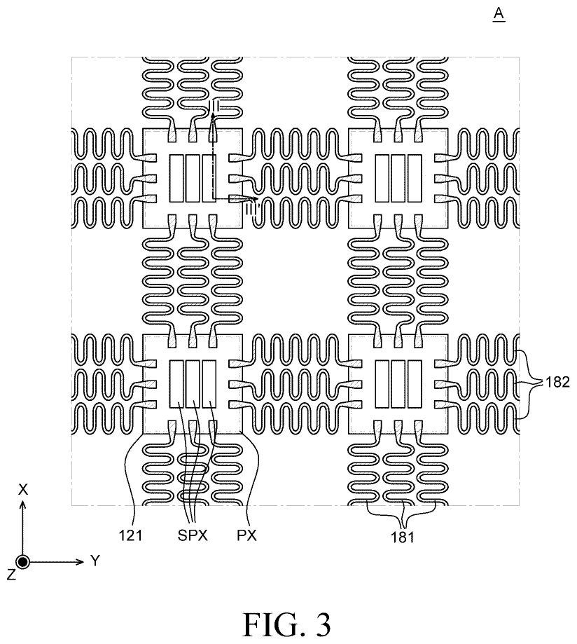

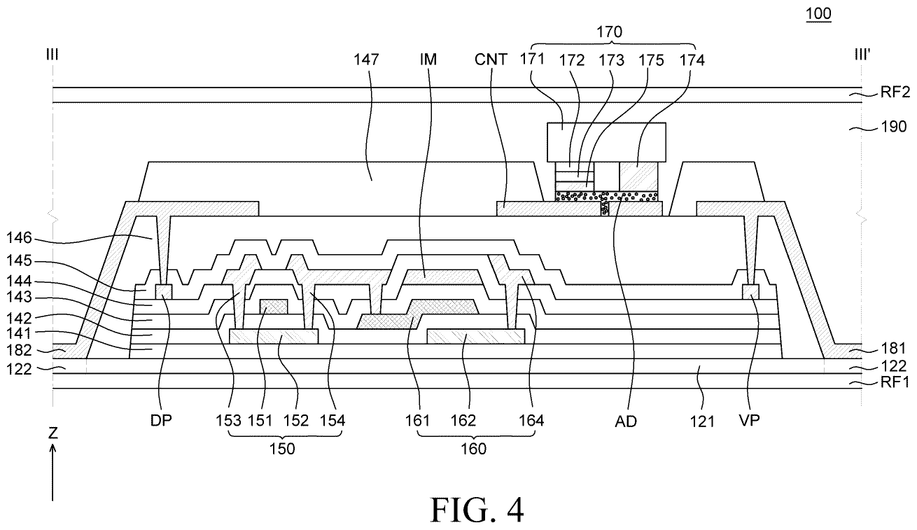

FIG. 1 is an exploded perspective view schematically illustrating a display device according to example embodiments of the present disclosure. FIG. 2 is a plan view illustrating an example of a display panel, a first resin film, and a second resin film included in the display device of FIG. 1. FIG. 3 is an enlarged plan view illustrating an example of a part A of FIG. 2. FIG. 4 is a cross-sectional view illustrating an example taken along the line III-III′ of FIG. 3.

First, referring to FIG. 1, a display device 1000 according to embodiment of the present disclosure can include a plate assembly Pass′y, a first resin film RF1, a display panel 100, a second resin film RF2, a touch panel 200, a third resin film RF3, and a functional layer 300. Referring to FIG. 2, a display panel 100 according to an example embodiment of the present disclosure can include a pattern layer 120, a plurality of pixels PX, a gate driver GD, a data driver DD, and a power supply PS. In one example embodiment of the present disclosure, referring to FIG. 4, the display panel 100 can further include a filling layer 190.

The display device 1000 can be stretchable along any one of a first direction X or a second direction Y which is different from the first direction X or can be two-dimensionally stretchable along the first direction X and the second direction Y. Further, the display device 1000 can also be three-dimensionally stretchable along a first direction X, a second direction Y, and a third direction Z.

In the meantime, for the convenience of description, hereinafter, a first length direction on the plane (for example, a horizontal direction) is illustrated as the first direction X and a second length direction on the plane (for example, a vertical direction) is illustrated as the second direction Y. For example, the plane defined by the first direction X and the second direction Y can be parallel to a plane of the display device 1000 and the second direction Y can be perpendicular to the first direction X. Further, a normal direction of a plane defined by the first direction X and the second direction Y, for example, a thickness direction of the display device 1000 can be defined as the third direction Z.

The plate assembly Pass′y is disposed on the bottom of the display device 1000 to support and protect components disposed above the plate assembly Pass′y. Further, the plate assembly Pass′y supports a first resin film RF1 and a display panel 100 having a bending or stretching property to suppress the sagging.

The plate assembly Pass′y can be used as a base material to be coated with the first resin film RF1 during a manufacturing process of the display device 1000. Specifically, after coating a resin composition on the plate assembly Pass′y, the display panel 100 is bonded and cured to form the first resin film RF1. Therefore, the plate assembly Pass′y can be bonded to the bottom of the display panel 100 by the first resin film RF1.

The first resin film RF1 is disposed on the plate assembly Pass′y. The first resin film RF1 is disposed between the plate assembly Pass′y and the display panel 100 to be in contact with each of the plate assembly Pass′y and the display panel 100. For example, the first resin film RF1 can be used as an adhesive layer which bonds the plate assembly Pass′y and the display panel 100.

The first resin film RF1 can be a substrate which supports and protects components consisting of the display panel 100. For example, the first resin film RF1 can be a substrate which supports a pattern layer 120 on which a pixel PX, a gate driver GD, and a power supply PS, as components of the display panel 100, are formed. Therefore, the first resin film RF1 can be referred to as a lower substrate.

The first resin film RF1 is a flexible film and can be reversibly expandable and contractible. The first resin film RF1 can include an insulation material which is bendable or stretchable. A material which configures the first resin film RF1 will be described below.

The first resin film RF1 can include an active area AA (or a display area) and a non-active area NA (or a non-display area) excluding the active area. For example, the non-active area NA can enclose the active area AA.

On the active area AA, a plurality of pixels PX each including a display element and a circuit element can be disposed.

Further, on the non-active area NA, a gate driver GD and a power supply PS for driving the plurality of pixels PX disposed in the active area AA can be disposed.

The pattern layer 120 can be disposed on the first resin film RF1.

In one example embodiment of the present disclosure, the pattern layer 120 can include a plurality of first plate patterns 121 and a plurality of first line patterns 122 disposed in the active area AA and a plurality of second plate patterns 123 and a plurality of second line patterns 124 disposed in the non-active area NA.

The plurality of first plate patterns 121 can be disposed in the active area AA of the first resin film RF1 and the plurality of pixels PX can be formed on the plurality of first plate patterns 121. The plurality of second plate patterns 123 can be disposed in the non-active area NA of the first resin film RF1 and the gate driver GD and the power supply PS can be formed on the plurality of second plate patterns 123.

Further, even though in FIG. 2, the plurality of first plate patterns 121 and the plurality of second plate patterns 123 have a quadrangular shape, the shape of the plurality of first plate patterns 121 and the plurality of second plate patterns 123 is not limited thereto and can vary in various forms.

Referring to FIG. 2, the pattern layer 120 can further include the plurality of first line patterns 122 disposed in the active area AA and the plurality of second line patterns 124 disposed in the non-active area NA.

The plurality of first line patterns 122 can be patterns which are disposed in the active area AA and connect the first plate patterns 121 which are adjacent to each other and can be referred to as first connection patterns.

The plurality of second line patterns 124 can be patterns which are disposed in the non-active area NA and connect the first plate patterns 121 and the second plate patterns 123 which are adjacent to each other or connect a plurality of second plate patterns 123 which is adjacent to each other.

The plurality of first line patterns 122 and second line patterns 124 can have a wavy shape (for example, a sine wave shape), but are not limited thereto. The plurality of first line patterns 122 and second line patterns 124 can extend in a zigzag shape or have various shapes such as a plurality of rhombic substrates which is connected at their vertexes to be extended.

In one example embodiment of the present disclosure, the plurality of first plate patterns 121, the plurality of first line patterns 122, the plurality of second plate patterns 123, and the plurality of second line patterns 124 can be rigid patterns. For example, the plurality of first plate patterns 121, the plurality of first line patterns 122, the plurality of second plate patterns 123, and the plurality of second line patterns 124 can be more rigid than the first resin film RF1 and a second resin film RF2 to be described below. Accordingly, moduli of elasticity and hardness of the plurality of first plate patterns 121, the plurality of first line patterns 122, the plurality of second plate patterns 123, and the plurality of second line patterns 124 can be higher than the moduli of elasticity and the hardness of the first resin film RF1 and the second resin film RF2. Moduli of elasticity of the plurality of first plate patterns 121, the plurality of first line patterns 122, the plurality of second plate patterns 123, and the plurality of second line patterns 124 can be 1000 times higher than the moduli of elasticity of the first resin film RF1 and the second resin film RF2, but it is not limited thereto.

The plurality of first plate patterns 121, the plurality of first line patterns 122, the plurality of second plate patterns 123, and the plurality of second line patterns 124 which are a plurality of rigid substrates can be formed of a plastic material having a lower flexibility than the first resin film RF1 and the second resin film RF2 to be described below.

The gate driver GD can supply a gate signal to the plurality of pixels PX disposed in the active area AA. The gate driver GD can include a plurality of stages formed on the plurality of second plate patterns 123 and each stage of the gate driver GD can be electrically connected to each other by means of the plurality of gate connection lines. Accordingly, a gate signal output from any one of stages can be transmitted to the other stage. Each stage can sequentially supply the gate signal to the plurality of pixels PX connected to each stage.

The power supply PS is connected to the gate driver GD to supply a gate driving voltage and a gate clock voltage. Further, the power supply PS is connected to the plurality of pixels PX to supply a pixel driving voltage to each of the plurality of pixels PX.

The printed circuit board PCB includes a controller, such as an IC chip or a circuit unit and/or a memory or a processor to transmit a signal and a voltage for driving the display element from the controller to the display element. The printed circuit board PCB can include a stretching area and a non-stretching area to ensure stretchability. For example, in the non-stretching area, an IC chip, a circuit unit, a memory, and a processor can be mounted and in the stretching area, wiring lines which are electrically connected to the IC chip, the circuit unit, the memory, and the processor can be disposed.

The data driver DD can supply a data voltage to the plurality of pixels PX disposed in the active area AA. The data driver DD can be mounted in the non-stretching area of the printed circuit board PCB.

Referring to FIGS. 2 and 3, the plurality of first plate patterns 121 can be disposed on the active area AA of the first resin film RF1. The plurality of first plate patterns 121 is spaced apart from each other to be disposed on the first resin film RF1. For example, as illustrated in FIG. 2, the plurality of first plate patterns 121 can be disposed on the first resin film RF1 in a matrix, but is not limited thereto.

Referring to FIGS. 3 and 4, a pixel PX including the plurality of sub pixels SPX can be disposed in the first plate pattern 121. Each of the sub pixels SPX can include an LED 170 which is a display element and a driving transistor 160 and a switching transistor 150 which drive the LED 170. However, in the sub pixel SPX, the display element is not limited to an LED, and can also be changed to an organic light emitting diode.

The plurality of sub pixels SPX can include a red sub pixel, a green sub pixel, and a blue sub pixel, but is not limited thereto and colors of the plurality of sub pixels SPX can be modified to various colors as needed.

The plurality of sub pixels SPX can be connected to a plurality of connection lines 181 and 182 (which are also sometimes referred to as a first connection line 181 and a second connection line 182).

Hereinafter, a cross-sectional structure of the display panel 100 in the active area AA will be described in more detail with reference to FIG. 4.

Referring to FIG. 4, a plurality of inorganic insulating layers can be disposed on the plurality of first plate patterns 121. For example, a plurality of inorganic insulating layers can include a buffer layer 141, a gate insulating layer 142, a first interlayer insulating layer 143, a second interlayer insulating layer 144, and a passivation layer 145. However, the example embodiment of the present disclosure is not limited thereto and various inorganic insulating layers are additionally disposed on the plurality of first plate patterns 121. One or more of the buffer layer 141, the gate insulating layer 142, the first interlayer insulating layer 143, the second interlayer insulating layer 144, and the passivation layer 145 which are inorganic insulating layers can be omitted.

The buffer layer 141 can be disposed on the plurality of first plate patterns 121. The buffer layer 141 includes an insulating material and can be formed on the plurality of first plate patterns 121 to protect various components of the display panel 100 from permeation of moisture (H₂O) and oxygen (O₂) from the outside of the first resin film RF1 and the plurality of first plate patterns 121. However, the buffer layer 141 can be omitted depending on a structure or a characteristic of the display panel 100.

In one example embodiment of the present disclosure, the buffer layer 141 can be formed only in an area where the first resin film RF1 overlaps the plurality of first plate patterns 121 and the plurality of second plate patterns 123. As described above, the buffer layer 141 can be formed of an inorganic material so that the buffer layer 141 can be cracked to be damaged during a process of stretching the display panel 100. Therefore, the buffer layer 141 is not formed in an area between the plurality of first plate patterns 121 and the plurality of second plate patterns 123. Instead, the buffer layer 141 is patterned to have a shape of the plurality of first plate patterns 121 and the plurality of second plate patterns 123 to be formed only above the plurality of first plate patterns 121 and the plurality of second plate patterns 123. Therefore, in the display panel 100 according to the example embodiment of the present disclosure and the display device 1000 including the same, the buffer layer 141 is formed only in an area overlapping the plurality of first plate patterns 121 and the plurality of second plate patterns 123 which are rigid patterns. Therefore, even though the display panel 100 is bent or extended to be deformed, the damage of various components of the display panel 100 can be suppressed.

A switching transistor 150 including a gate electrode 151, an active layer 152, a source electrode 153, and a drain electrode 154 and a driving transistor 160 including a gate electrode 161, an active layer 162, a source electrode and a drain electrode 164 can be disposed on the buffer layer 141.

The active layer 152 of the switching transistor 150 and the active layer 162 of the driving transistor 160 can be disposed on the buffer layer 141. For example, the active layer 152 of the switching transistor 150 and the active layer 162 of the driving transistor 160 can be formed of oxide semiconductor or amorphous silicon (a-Si), polycrystalline silicon (poly-Si), or an organic semiconductor.

The gate insulating layer 142 can be disposed on the active layer 152 of the switching transistor 150 and the active layer 162 of the driving transistor 160. The gate insulating layer 142 can include an insulating material and electrically insulate the gate electrode 151 of the switching transistor 150 from the active layer 152 of the switching transistor 150 and electrically insulate the gate electrode 161 of the driving transistor 160 from the active layer 162 of the driving transistor 160.

The gate electrode 151 of the switching transistor 150 and the gate electrode 161 of the driving transistor 160 can be disposed on the gate insulating layer 142. The gate electrode 151 of the switching transistor 150 and the gate electrode 161 of the driving transistor 160 can be disposed on the gate insulating layer 142 to be spaced apart from each other. The gate electrode 151 of the switching transistor 150 can overlap the active layer 152 of the switching transistor 150 and the gate electrode 161 of the driving transistor 160 can overlap the active layer 162 of the driving transistor 160.

The first interlayer insulating layer 143 can be disposed on the gate electrode 151 of the switching transistor 150 and the gate electrode 161 of the driving transistor 160. The first interlayer insulating layer 143 can include an insulating material and insulate the gate electrode 161 of the driving transistor 160 from an intermediate metal layer IM.

The intermediate metal layer IM including a metal material can be disposed on the first interlayer insulating layer 143. The intermediate metal layer IM can overlap the gate electrode 161 of the driving transistor 160. Therefore, a storage capacitor can be formed in an overlapping area of the intermediate metal layer IM and the gate electrode 161 of the driving transistor 160. For example, the gate electrode 161 of the driving transistor 160, the first interlayer insulating layer 143, and the intermediate metal layer IM can form the storage capacitor. However, the placement area of the intermediate metal layer IM is not limited thereto and the intermediate metal layer IM overlaps the other electrode to form the storage capacitor in various forms.

The second interlayer insulating layer 144 can be disposed on the intermediate metal layer IM. The second interlayer insulating layer 144 can include an insulating material and insulate the gate electrode 151 of the switching transistor 150 from the source electrode 153 and the drain electrode 154 of the switching transistor 150. The second interlayer insulating layer 144 can insulate the intermediate metal layer IM from the source electrode and the drain electrode 164 of the driving transistor 160.

The source electrode 153 and the drain electrode 154 of the switching transistor 150 can be disposed on the second interlayer insulating layer 144. The source electrode and the drain electrode 164 of the driving transistor 160 can be disposed on the second interlayer insulating layer 144. The source electrode 153 and the drain electrode 154 of the switching transistor 150 can be disposed on the same layer to be spaced apart from each other.

Even though in FIG. 4, the source electrode of the driving transistor 160 is omitted, the source electrode of the driving transistor 160 can also be disposed to be spaced apart from the drain electrode 164 on the same layer. In the switching transistor 150, the source electrode 153 and the drain electrode 154 can be in contact with the active layer 152 to be electrically connected to the active layer 152. In the driving transistor 160, the source electrode and the drain electrode 164 can be in contact with the active layer 162 to be electrically connected to the active layer 162. The drain electrode 154 of the switching transistor 150 is in contact with the gate electrode 161 of the driving transistor 160 through a contact hole to be electrically connected to the gate electrode 161 of the driving transistor 160.

A gate pad, a data pad DP, and a voltage pad VP can be disposed on the second interlayer insulating layer 144.

Specifically, the gate pad can transmit a gate signal to the plurality of sub pixels SPX. The gate pad can be connected to the first connection line 181 through a contact hole. The gate signal supplied from the first connection line 181 can be transmitted to the gate electrode 151 of the switching transistor 150 from the gate pad through a wiring line formed on the first plate pattern 121.

The data pad DP can transmit a data voltage to the plurality of sub pixels SPX. The data pad DP can be connected to the second connection line 182 through a contact hole. The data voltage supplied from the second connection line 182 can be transmitted to the source electrode 153 of the switching transistor 150 from the data pad DP through a wiring line formed on the first plate pattern 121.

The voltage pad VP can transmit a low potential voltage to the plurality of sub pixels SPX. The voltage pad VP can be connected to the first connection line 181 through a contact hole. The low potential voltage supplied from the first connection line 181 can be transmitted to the n-electrode 174 of the LED 170 from the voltage pad VP through a wiring line formed on the first plate pattern 121.

The gate pad and the data pad DP can be formed of the same material as the source electrode 153 and the drain electrodes 154 and 164, but are not limited thereto.

The passivation layer 145 can be formed on the switching transistor 150 and the driving transistor 160. For example, the passivation layer 145 can be disposed to cover the switching transistor 150 and the driving transistor 160 to protect the switching transistor 150 and the driving transistor 160 from the permeation of moisture and oxygen. The passivation layer 145 can be formed of an inorganic material and configured by a single layer or a double layer, but is not limited thereto.

The gate insulating layer 142, the first interlayer insulating layer 143, the second interlayer insulating layer 144, and the passivation layer 145 are patterned to be formed only in an area overlapping the plurality of first plate patterns 121. The gate insulating layer 142, the first interlayer insulating layer 143, the second interlayer insulating layer 144, and the passivation layer 145 can also be formed of the inorganic material, similar to the buffer layer 141. As such, the gate insulating layer 142, the first interlayer insulating layer 143, the second interlayer insulating layer 144, and the passivation layer 145 can also be easily cracked to be damaged during the process of stretching the display panel 100 or the display device 1000. Therefore, the gate insulating layer 142, the first interlayer insulating layer 143, the second interlayer insulating layer 144, and the passivation layer 145 are not formed in an area between the plurality of first plate patterns 121. However, the gate insulating layer 142, the first interlayer insulating layer 143, the second interlayer insulating layer 144, and the passivation layer 145 are patterned to have a shape of the plurality of first plate patterns 121 to be formed only above the plurality of first plate patterns 121.

The planarization layer 146 can be formed on the passivation layer 145. The planarization layer 146 can planarize upper portions of the switching transistor 150 and the driving transistor 160. The planarization layer 146 can be configured by a single layer or a plurality of layers and can be formed of an organic material.

The planarization layer 146 can be disposed so as to cover top surfaces and side surfaces of the buffer layer 141, the gate insulating layer 142, the first interlayer insulating layer 143, the second interlayer insulating layer 144, and the passivation layer 145 on the plurality of first plate patterns 121. The planarization layer 146 can be disposed so as to enclose the buffer layer 141, the gate insulating layer 142, the first interlayer insulating layer 143, the second interlayer insulating layer 144, and the passivation layer 145 together with the plurality of first plate patterns 121. Specifically, the planarization layer 146 can be disposed so as to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of first plate patterns 121. Accordingly, the planarization layer 146 can supplement a step on side surfaces of the buffer layer 141, the gate insulating layer 142, the first interlayer insulating layer 143, the second interlayer insulating layer 144, and the passivation layer 145. Further, the planarization layer 146 can enhance an adhesive strength of the connection lines 181 and 182 disposed on a side surface of the planarization layer 146.

An inclination angle of the side surface of the planarization layer 146 can be smaller than an inclination angle formed by side surfaces of the buffer layer 141, the gate insulating layer 142, the first interlayer insulating layer 143, the second interlayer insulating layer 144, and the passivation layer 145. For example, the side surface of the planarization layer 146 can have a slope which is gentler than a slope formed by each of the side surface of the passivation layer 145, the side surface of the first interlayer insulating layer 143, the side surface of the second interlayer insulating layer 144, the side surface of the gate insulating layer 142, and the side surface of the buffer layer 141. Therefore, the connection lines 181 and 182 which are disposed to be in contact with the side surface of the planarization layer 146 are disposed with a gentle slope so that when the display panel 100 is stretched, the stress generated in the connection lines 181 and 182 can be reduced. Further, the side surface of the planarization layer 146 has a relatively gentle slope so that the crack of the connection lines 181 and 182 or separation thereof from the side surface of the planarization layer 146 can be suppressed.

Referring to FIGS. 3 and 4, the connection lines 181 and 182 can electrically connect the pads on the plurality of first plate patterns 121. The connection lines 181 and 182 can be disposed on the plurality of first line patterns 122. The connection lines 181 and 182 can extend onto the plurality of first plate patterns 121 to be electrically connected to the gate pad and the data pad DP on the plurality of first plate patterns 121. In the meantime, the first line pattern 122 may not be disposed in an area where the connection lines 181 and 182 are not disposed, among areas between the plurality of first plate patterns 121.

The connection lines 181 and 182 can include a first connection line 181 and a second connection line 182. The first connection line 181 and the second connection line 182 include a metal material and can be disposed between the plurality of first plate patterns 121.

To be more specific, the first connection line 181 can refer to a wiring line extending in a first direction X between the plurality of first plate patterns 121, among the connection lines 181 and 182. The second connection line 182 can refer to a wiring line extending in a second direction Y between the plurality of first plate patterns 121, among the connection lines 181 and 182.

In the meantime, in the case of a display panel of a general display device, various wiring lines such as a plurality of gate lines and a plurality of data lines extend between the plurality of sub pixels as a straight line and the plurality of sub pixels is connected to one signal line. Therefore, in the display panel of the general display device, various wiring lines, such as a gate line, a data line, a high potential voltage line, and a reference voltage line, extend from one side to the other side of the display panel of the organic light emitting display device without being disconnected on the substrate.

In contrast, in the case of the display panel 100 included in the display device 1000 according to the example embodiment of the present disclosure, various wiring lines, such as a gate line, a data line, a high potential voltage line, a reference voltage line, or an initialization voltage line having a straight line shape which are considered to be used for the display panel of the general display device, can be disposed only on the plurality of first plate patterns 121 and the plurality of second plate patterns 123. For example, in the display panel 100 included in the display device 1000 according to the example embodiment of the present disclosure, a linear wiring line can be disposed only on the plurality of first plate patterns 121 and the plurality of second plate patterns 123.

In the display panel 100 of the display device 1000 according to the example embodiment of the present disclosure, the pads on the two adjacent first plate patterns 121 can be connected by the connection lines 181 and 182. Accordingly, the connection lines 181 and 182 can electrically connect the gate pads or the data pads DP on two adjacent first plate patterns 121. Accordingly, the display panel 100 included in the display device 1000 according to the example embodiment of the present disclosure can include a plurality of connection lines 181 and 182 which electrically connects various wiring lines, such as a gate line, a data line, a high potential voltage line, and a reference voltage line, between the plurality of first plate patterns 121. For example, the gate line can be disposed on the plurality of first plate patterns 121 disposed to be adjacent to each other in the first direction X and the gate pad can be disposed on both ends of the gate line. At this time, the plurality of gate pads on the plurality of first plate patterns 121 adjacent to each other in the first direction X can be connected to each other by the first connection line 181 which serves as a gate line. Therefore, the gate line disposed on the plurality of first plate patterns 121 and the first connection line 181 disposed on the first line pattern 122 can serve as one gate line. The above-described gate line can be referred to as a scan signal line. Further, wiring lines which extend in the first direction X, among all various wiring lines which can be included in the display panel 100, such as an emission signal line, a low potential voltage line, and a high potential voltage line, can also be electrically connected by the first connection line 181, as described above.

Referring to FIGS. 3 and 4, the first connection lines 181 can connect the gate pads on two first plate patterns 121 which are disposed side by side, among the gate pads on the plurality of first plate patterns 121 disposed to be adjacent in the first direction X. The first connection line 181 can serve as a gate line, an emission signal line, a high potential voltage line, or a low potential voltage line, but is not limited thereto. The gate pads on the plurality of first plate patterns 121 disposed in the first direction X can be connected by the first connection line 181 serving as a gate line, and transmit one gate signal.

The second connection line 182 can connect the data pads DP on two first plate patterns 121 which are disposed side by side, among the data pads DP on the plurality of first plate patterns 121 disposed to be adjacent in the second direction Y. The second connection line 182 can serve as a data line, a high potential voltage line, a low potential voltage line, or a reference voltage line, but is not limited thereto. The internal line on the plurality of first plate patterns 121 disposed in the second direction Y can be connected by the plurality of second connection lines 182 serving as a data line, and transmit one data voltage.

In the meantime, referring to FIG. 4, a bank 147 can be formed on the connection pad CNT, the connection lines 181 and 182, and the planarization layer 146. The bank 147 can include an insulating material and divide adjacent sub pixels SPX. The bank 147 can be disposed so as to cover at least a part of the connection lines 181 and 182 and the planarization layer 146. Even though in FIG. 4, it is illustrated that a height of the bank 147 is lower than a height of the LED 170, the present disclosure is not limited thereto and the height of the bank 147 can be equal to the height of the LED 170.

The LED 170 can be disposed on the connection pad CNT and the first connection line 181. The LED 170 can include an n-type layer 171, an active layer 172, a p-type layer 173, an n-electrode 174, and a p-electrode 175. The LED 170 of the display panel 100 according to the example embodiment of the present disclosure can have a flip-chip structure in which the n-electrode 174 and the p-electrode 175 are formed on one surface, but is not limited thereto.

The n-type layer 171 can be formed by injecting an n-type impurity into gallium nitride (GaN) having excellent crystallinity. The n-type layer 171 can be disposed on a separate base substrate which is formed of a material which is capable of emitting light.

The active layer 172 can be disposed on the n-type layer 171. The active layer 172 is an emission layer which emits light in the LED 170 and can be formed of a nitride semiconductor, for example, indium gallium nitride (InGaN). The p-type layer 173 can be disposed on the active layer 172. The p-type layer 173 can be formed by injecting a p-type impurity into gallium nitride (GaN).

As described above, the LED 170 according to the example embodiment of the present disclosure can be manufactured by sequentially laminating the n-type layer 171, the active layer 172, and the p-type layer 173, and then etching a predetermined part to form the n-electrode 174 and the p-electrode 175. In this case, the predetermined part which is a space for separating the n-electrode 174 and the p-electrode 175 from each other can be etched to expose a part of the n-type layer 171. In other words, the surfaces of the LED 170 on which the n-electrode 174 and the p-electrode 175 are disposed are not flat surfaces, but can have different heights.

As described above, the n-electrode 174 can be disposed in the etched area and can be formed of a conductive material. The p-electrode 175 can be disposed in an area which is not etched and can also be formed of a conductive material. For example, the n-electrode 174 can be disposed on the n-type layer 171 which is exposed by the etching process and the p-electrode 175 can be disposed on the p-type layer 173. The p-electrode 175 can be formed of the same material as the n-electrode 174.

A conductive adhesive layer AD is disposed on top surfaces of the connection pad CNT and the first connection line 181 and between the connection pad CNT and the first connection line 181 so that the LED 170 can be adhered onto the connection pad CNT and the first connection line 181. At this time, the n-electrode 174 can be disposed on the first connection line 181 and the p-electrode 175 can be disposed on the connection pad CNT.

The conductive adhesive layer AD can be an adhesive layer in which conductive balls are dispersed in an insulating base member to have a conductivity. When heat or pressure is applied to the conductive adhesive layer AD, the conductive balls are electrically connected in a portion applied with heat or pressure to have a conductive property and an area which is not pressurized can have an insulating property. For example, the n-electrode 174 can be electrically connected to the first connection line 181 by means of the conductive adhesive layer AD and the p-electrode 175 can be electrically connected to the connection pad CNT by means of the conductive adhesive layer AD. After applying the conductive adhesive layer AD onto the top surface of the first connection line 181 and the connection pad CNT by an inkjet method, the LED 170 is transferred onto the conductive adhesive layer AD and is pressurized and heated. By doing this, the connection pad CNT can be electrically connected to the p-electrode 175 and the first connection line 181 can be electrically connected to the n-electrode 174. However, the other part of the conductive adhesive layer AD excluding a part of the conductive adhesive layer AD disposed between the n-electrode 174 and the first connection line 181 and a part of the conductive adhesive layer AD disposed between the p-electrode 175 and the connection pad CNT can have an insulation property. In the meantime, the conductive adhesive layer AD can be divided to be disposed on the connection pad CNT and the first connection line 181, respectively.

The connection pad CNT is electrically connected to the drain electrode 164 of the driving transistor 160 to be applied with a driving voltage from the driving transistor 160 to drive the LED 170. Even though in FIG. 4, it is illustrated that the connection pad CNT is not in direct contact with the drain electrode 164 of the driving transistor 160, but is in indirect contact therewith, the present disclosure is not limited thereto. Therefore, the connection pad CNT and the drain electrode 164 of the driving transistor 160 can be in direct contact with each other. Further, a low potential driving voltage can be applied to the first connection line 181 to drive the LED 170. Therefore, when the display panel 100 is turned on, different voltage levels applied to the connection pad CNT and the first connection line 181 are transmitted to the n-electrode 174 and the p-electrode 175 so that the LED 170 can emit light.

The second resin film RF2 supports various components disposed below the second resin film RF2. The second resin film RF2 can be a substrate which covers and protects various components of the display panel 100. For example, the second resin film RF2 can be a substrate which covers a pixel PX, a gate driver GD, and a power supply PS, which are components of the display panel 100. Therefore, the second resin film RF2 can be referred to as an upper substrate.

The second resin film RF2 is disposed between the display panel 100 and the touch panel 200 to bond the display panel 100 and the touch panel 200. Specifically, the second resin film RF2 is formed by curing after coating a material which configures the second resin film RF2 on the display panel 100 and then bonding the touch panel 200. Therefore, the second resin film RF2 can be disposed so as to be in direct contact with the display panel 100 and the touch panel 200, respectively.

The second resin film RF2 can be formed of the same material as the first resin film RF1. Therefore, the second resin film RF2 can include an insulating material which is bendable or stretchable and is a flexible film which is reversibly expandable or contractible. A material which configures the second resin film RF2 will be described below.

A polarization layer can be disposed on the second resin film RF2. The polarization layer can function to polarize light incident from the outside of the display panel 100 to reduce the external light reflection. Further, an optical film other than the polarization layer can be disposed on the second resin film RF2.

Further, a filling layer 190 can be disposed on the entire first resin film RF1 to be filled between components disposed on the second resin film RF2 and the first resin film RF1. The filling layer 190 can be configured by a curable adhesive. Specifically, the material which configures the filling layer 190 is coated on the entire surface of the first resin film RF1 and then is cured so that the filling layer 190 can be disposed between the components disposed on the second resin film RF2 and the first resin film RF1. For example, the filling layer 190 can be an optically clear adhesive (OCA) and can be configured by an acrylic adhesive, a silicon-based adhesive, and a urethane-based adhesive. According to an example embodiment of the present disclosure, the filling layer 190 can be omitted and a material which configures the second resin film RF2 is coated on the entire surface of the first resin film RF1 and then is bonded and cured to the touch panel 200 to bond the display panel 100 and the touch panel 200.

The touch panel 200 can include a material which responds to the stretching of the display device 1000. The touch panel 200 is disposed above the display panel 100 and can have a shape corresponding to the display panel 100, for example, a shape corresponding to the first resin film RF1 which supports the display panel 100.

For example, the touch panel 200 can include a base substrate (or a touch base substrate), a plurality of touch sensing films disposed on the base substrate, a plurality of touch lines which is disposed in different directions on the base substrate and the plurality of touch sensing films, a plurality of routing lines, and a plurality of link lines. The plurality of routing lines is connected to the plurality of touch lines to transmit a touch signal detected by the plurality of touch lines and the plurality of link lines connects the plurality of routing lines and the touch circuit unit.

The base substrate can support the plurality of touch sensing films, the plurality of touch lines, the plurality of routing lines, and the plurality of link lines. The base substrate is a flexible substrate and is reversibly expandable and contractible.

The plurality of touch sensing films can be disposed on the active area AA of the base substrate to be spaced apart from each other with a predetermined distance. In one example embodiment of the present disclosure, a size of each of the plurality of touch sensing films can correspond to a size of each of the plurality of first plate patterns 121 disposed on the display panel 100 which has been described with reference to FIG. 2. In one example embodiment of the present disclosure, the plurality of touch sensing films can include a touch sensing material. For example, the plurality of touch sensing films can include a touch base film which is formed of a bendable or stretchable insulating material and a touch sensing material which is dispersed in the touch base film in the form of particles, but is not limited thereto.

A plurality of touch lines which detects the touch can be disposed above and below the touch sensing film.

The plurality of touch lines can include a plurality of first touch lines disposed in the first direction X and the plurality of second touch lines disposed in the second direction Y so as to intersect the plurality of first touch lines with the touch sensing film therebetween, on the active area AA of the base substrate. The intersecting area of the plurality of first touch lines and the plurality of second touch lines is defined as a touch sensing area and a plurality of touch sensing films can be disposed so as to overlap the touch sensing area. Accordingly, the touch panel 200 can sense a touch coordinate and a touch input using a resistance change of the touch sensing film with respect to the touch input.

The plurality of touch lines can have a straight line shape in an area which overlaps the plurality of touch sensing films (for example, the touch sensing area), and have a curved shape in the other area.

As described above, a plurality of touch sensing films of the touch panel 200 of the display device 1000 according to the example embodiments of the present disclosure is disposed to be spaced apart from each other on the base substrate which is a flexible substrate and is disposed in an area overlapping the first plate pattern 121 of the display panel 100. By doing this, when the display panel 100 is stretched in both directions, the touch panel 200 can also be stretched in both directions.

The plurality of routing lines can be disposed on the non-active area NA of the base substrate and can be connected to the plurality of touch lines disposed in the active area AA. Accordingly, a touch signal detected by the plurality of touch lines can be transmitted to the plurality of routing lines.

The plurality of routing lines can have a curved shape to ensure the stretchability of the touch panel 200.

The plurality of link lines can electrically connect the plurality of routing lines and the touch circuit unit. Accordingly, the touch signal which is detected by the plurality of touch lines to be transmitted to the plurality of routing lines can be transmitted to the touch circuit unit through the plurality of link lines. Therefore, the touch circuit unit can detect a touch (for example, a user's touch) input from the outside.

A third resin film RF3 can be disposed above the touch panel 200. The third resin film RF3 covers various components of the display panel 100 and the touch panel 200 and protects the display panel 100 and the touch panel 200 from external shocks or moisture. Therefore, the third resin film RF3 can be referred to as a cover member.

The third resin film RF3 can be formed of the same material as the first resin film RF1 and the second resin film RF2. Therefore, the third resin film RF3 can include an insulating material which is bendable or stretchable and is a flexible film which is reversibly expandable or contractible. A material which configures the third resin film RF3 will be described below.

The functional layer 300 can be formed above the third resin film RF3. For example, the functional layer 300 can include at least one layer selected from an anti-fingerprint layer, an anti-reflection layer, and an anti-contamination layer. The functional layer 300 can be coated on a top surface of the third resin film RF3 and can improve a surface quality and a display quality of the display device 1000.

The third resin film RF3 is disposed between the functional layer 300 and the touch panel 200 to bond the functional layer 300 and the touch panel 200. Therefore, the third resin film RF3 is disposed so as to be in direct contact with the functional layer 300 and the touch panel 200. For example, the third resin film RF3 can bond the functional layer 300 and the touch panel 200 and can also serve as a cover member.

In one example embodiment of the present disclosure, the display device 1000 includes the first resin film RF1 as a lower substrate and the second resin film RF2 as an upper substrate and includes the third resin film RF3 as a cover member.

The first resin film RF1, the second resin film RF2, and the third resin film RF3 can be a stretching film and include an insulating material which is bendable or stretchable. Therefore, the first resin film RF1, the second resin film RF2, and the third resin film RF3 can have a flexible property and can be reversibly expandable and contractible.

A modulus of elasticity of each of the first resin film RF1, the second resin film RF2, and the third resin film RF3 can be 7 MPa or lower. According to an example embodiment of the present disclosure, a ductile breaking rate of each of the first resin film RF1, the second resin film RF2, and the third resin film RF3 can be 400% or higher. Here, the ductile breaking rate refers to a stretching rate at a timing when an object to be stretched is broken or cracked. Specifically, for example, the modulus of elasticity of each of the first resin film RF1, the second resin film RF2, and the third resin film RF3 can be 3.7 MPa and the ductile breaking rate can be 800%. According to another example embodiment of the present disclosure, the modulus of elasticity of each of the first resin film RF1, the second resin film RF2, and the third resin film RF3 can be 4.4 MPa and the ductile breaking rate can be 550%.

The first resin film RF1, the second resin film RF2, and the third resin film RF3 can be formed of the same material. Each of the first resin film RF1, the second resin film RF2, and the third resin film RF3 can be a flexible film including urethane acrylate and two types of photoinitiators. Specifically, each of the first resin film RF1, the second resin film RF2, and the third resin film RF3 can be formed by coating and then curing a resin composition including urethane acrylate and two types of photoinitiators. If necessary, the resin composition can optionally further include an additive, such as a dye or a pigment.

The urethane acrylate refers to a compound including both urethane bond and acrylate. In the example embodiment of the present disclosure, the urethane acrylate can be acrylate-modified urethane or urethane in which both ends are capped with acrylate. For example, the urethane acrylate can be a compound expressed by the following Formula, but is not limited thereto. For example, the compound of the following Formula can be obtained by synthesizing dicarboxylic acid or polycarboxylic acid and diisocyanate from hydroxy alkyl acrylate, but is not limited thereto.

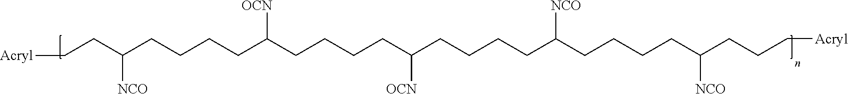

In Formula, acryl can be an acrylate functional group and n can be an integer of 1 or larger.

Two types of photoinitiators can be photoinitiators having different absorption wavelengths. For example, the photoinitiator can include a first photoinitiator having an absorption wavelength of 400 nm or higher and a second photoinitiator having an absorption wavelength of 370 nm or lower. Therefore, each of the first resin film RF1, the second resin film RF2, and the third resin film RF3 implements an adhesiveness by primarily curing a resin composition including two types of photoinitiators having different absorption wavelengths and can be formed by completely curing by means of secondary curing. Therefore, each of the first resin film RF1, the second resin film RF2, and the third resin film RF3 can serve as a substrate which supports or covers some components and also bond layers above and/or below the resin film.

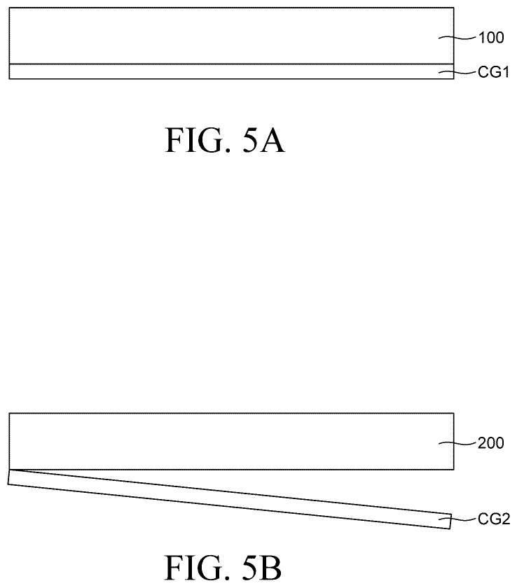

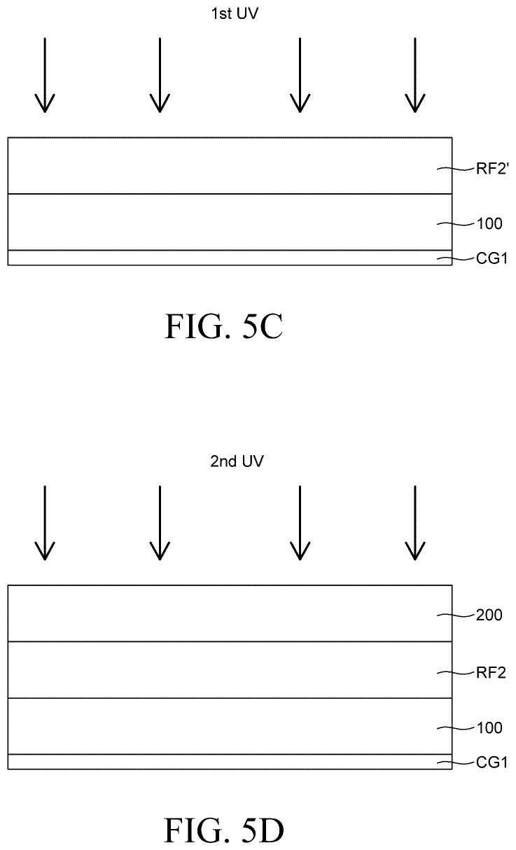

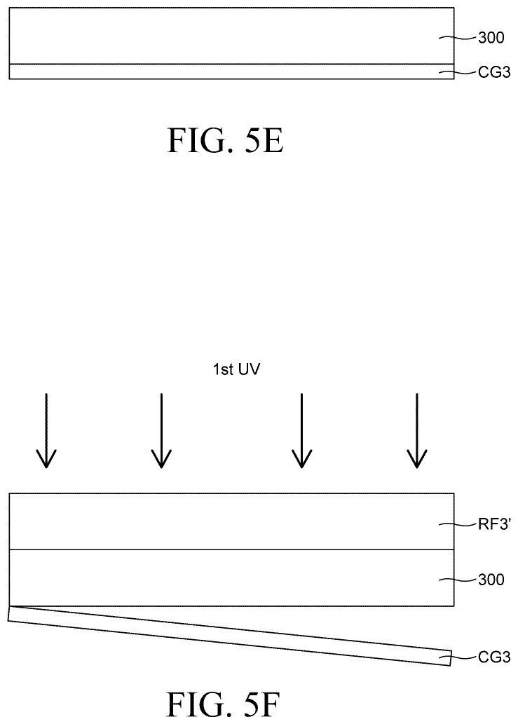

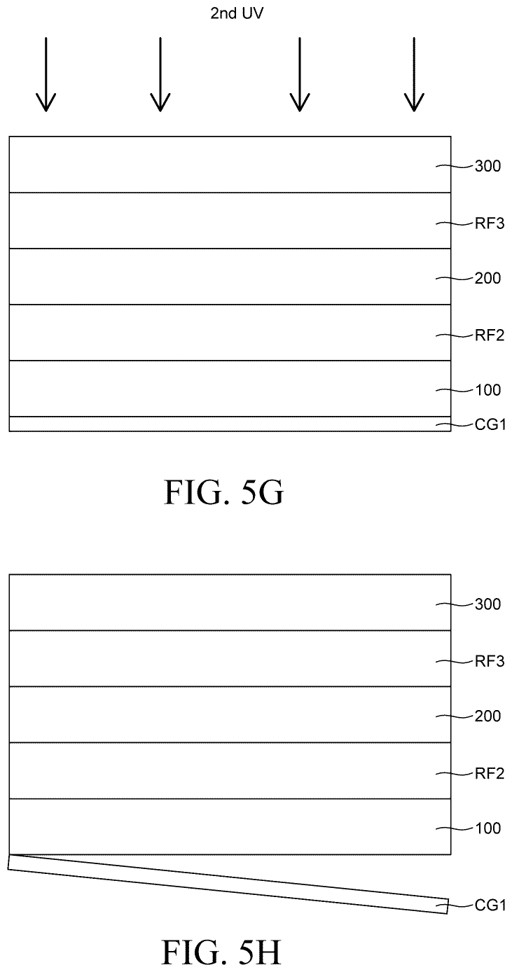

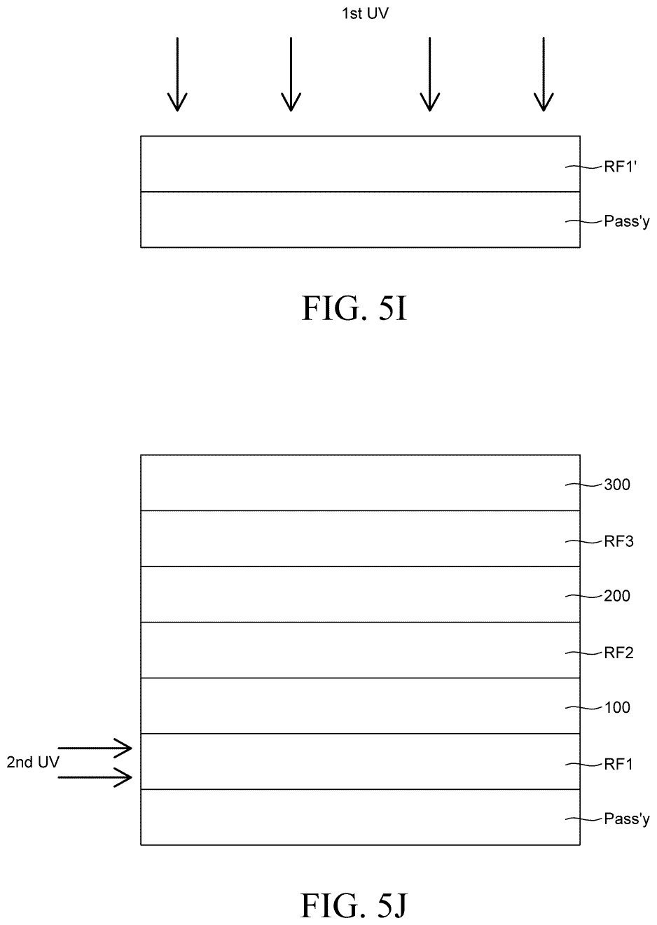

Hereinafter, a manufacturing method of a display device according to an example embodiment of the present disclosure will be described with reference to FIGS. 5A to 5J. FIGS. 5A to 5J are cross-sectional views for explaining a manufacturing method of a display device according to an example embodiment of the present disclosure.

Referring to FIG. 5A, the display device 1000 can be formed by a laser lift off process. Next, a display panel 100 including a pattern layer 120 is formed on a carrier substrate CG1. The display panel 100 including the pattern layer 120 can be formed by a known method in the art. A sacrificial layer can be formed on one surface of the carrier substrate CG on which the pattern layer 120 is to be formed to make it easy to perform the laser lift off process.

Referring to FIG. 5B, a touch panel 200 is formed on the carrier substrate CG2 and the carrier substrate CG2 is separated by the laser lift off process to manufacture the touch panel 200.

Referring to FIG. 5C, a resin composition including urethane acrylate and two types of photoinitiators is coated and is primarily cured on the display panel 100 to form a semi-cured second resin film RF2′. The resin composition can be coated on the entire surface of the display panel 100 or can be spirally applied. After coating the resin composition, the UV is irradiated to primarily cure the resin composition to form the semi-cured second resin film RF2′. In this step, UV with a first energy is irradiated to cure the resin composition. For example, the intensity of irradiated UV can be 1000 mW/cm² and a dose of UV light can be 5000 mJ/cm², but are not limited thereto. When the UV with a first energy is irradiated, the first photoinitiator of the resin composition is activated to perform the curing reaction.

Referring to FIG. 5D, the touch panel 200 is disposed on the semi-cured second resin film RF2′ and is subject to the secondary curing to form a second resin film RF2. The semi-cured second resin film RF2′ has an adhesive characteristic to bond the touch panel 200 onto the display panel 100. For the secondary curing, UV with a second energy which is higher than the first energy can be irradiated. For example, the intensity of UV irradiated in the secondary curing step can be 1000 mW/cm² and a dose of UV light can be 10,000 mJ/cm², but are not limited thereto. When the UV with the second energy is irradiated, the second photoinitiator of the semi-cured second resin film RF2′ is activated to perform the curing reaction. In this step, the UV having a second energy higher than that in the primary curing step is irradiated to form a fully cured second resin film RF2.

Referring to FIG. 5E, a functional layer 300 is formed on the carrier substrate CG3. The functional layer 300 is coated on the entire surface of the carrier substrate CG3.

Referring to FIG. 5F, the carrier substrate CG3 is separated from the functional layer 300. The carrier substrate CG3 can be separated from the functional layer 300 by the laser lift process. After separating the carrier substrate CG3, a resin composition is coated on the functional layer 300 and is primarily cured to form a semi-cured third resin film RF3′. The resin composition can include the same material as the resin composition which has been described in FIG. 5C. The resin composition can be coated on the entire surface of the functional layer 300 or can be spirally applied. After coating the resin composition, the UV is irradiated to primarily cure the resin composition. In this step, UV with a first energy is irradiated to cure the resin composition. For example, the intensity of irradiated UV can be 1000 mW/cm² and a dose of UV light can be 5000 mJ/cm², but are not limited thereto. When the UV with a first energy is irradiated, the first photoinitiator of the resin composition is activated to perform the curing reaction. Therefore, the semi-cured third resin film RF3′ can be formed.

Next, referring to FIG. 5G, the semi-cured third resin film RF3′ is disposed on the display panel 200 so as to be opposite to the touch panel 200 according to the process illustrated in FIG. 5D. The semi-cured third resin film RF3′ has an adhesive characteristic to bond the functional layer 300 onto the touch panel 200. The semi-cured third resin film RF3′ is irradiated with UV to be secondarily cured to form the fully-cured third resin film RF3. The secondary curing can be performed by irradiating UV with a second energy which is higher than the first energy. For example, the intensity of UV irradiated in the secondary curing step can be 1000 mW/cm² and a dose of UV light can be 10,000 mJ/cm², but are not limited thereto. When the UV with the second energy is irradiated, the second photoinitiator of the semi-cured third resin film RF3′ is activated to perform the curing reaction. In this step, the UV having a second energy higher than that in the primary curing step is irradiated to form a fully cured third resin film RF3.

Referring to FIG. 5H, the carrier substrate CG1 is separated from a device according to the previous process of FIG. 5G. The carrier substrate CG1 can be separated from the display panel 100 by the laser lift process.

Next, referring to FIG. 5I, a plate assembly Pass′y is prepared, a resin composition is coated above the plate assembly Pass′y and is subject to the primary curing to form a semi-coated first resin film RF1′. The resin composition can include the same material as the resin composition which has been described in FIG. 5C. The resin composition can be coated on the entire surface of the plate assembly Pass′y or can be spirally applied. After coating the resin composition, the UV is irradiated to primarily cure the resin composition to form the semi-cured first resin film RF1′. In this step, UV with a first energy is irradiated to cure the resin composition. For example, the intensity of irradiated UV can be 1000 mW/cm² and a dose of UV light can be 5000 mJ/cm², but are not limited thereto. When the UV with a first energy is irradiated, the first photoinitiator of the resin composition is activated to perform the curing reaction.

Referring to FIG. 5J, the display panel 100 is disposed on the first resin film RF1′ which is semi-cured so as to be opposite to the display panel 100 of FIG. 5H. The semi-cured first resin film RF1′ has an adhesive characteristic to bond the display panel 100 and the plate assembly Pass′y. The semi-cured first resin film RF1′ is secondarily cured to form the first resin film RF1. For the secondary curing, UV with a second energy which is higher than the first energy can be irradiated. For example, the intensity of UV irradiated in the secondary curing step is 1000 mW/cm² and a dose of UV light can be 10,000 mJ/cm², but are not limited thereto. When the UV with the second energy is irradiated, the second photoinitiator of the semi-cured first resin film RF1′ is activated to perform the curing reaction. In this step, the UV having a second energy higher than that in the primary curing step is irradiated to form a fully cured first resin film RF1. By doing this, the display device 1000 according to the example embodiment of the present disclosure is manufactured.

The manufacturing process of the display device illustrated in FIGS. 5A to 5J is an example, but is not limited thereto. For example, after the process illustrated in FIG. 5D, the process can be performed by forming the semi-cured third resin film RF3′ on the touch panel 200 and coating the functional layer 300 thereabove, and then performing the secondary curing. The first resin film RF1, the second resin film RF2, and the third resin film RF3 can have moduli of elasticity and thicknesses which are the same or different. The modulus of elasticity of each of the first resin film RF1, the second resin film RF2, and the third resin film RF3 can be controlled by varying a content of an initiator in the resin composition, the intensity of UV irradiated on the resin composition, and a dose of UV light.

In the example embodiment of the present disclosure, the modulus of elasticity of each of the first resin film RF1, the second resin film RF2, and the third resin film RF3 can be 3 MPa to 5 MPa.

In the example embodiment of the present disclosure, a thickness of the first resin film RF1 can be 100 um to 800 um, a thickness of the second resin film RF2 can be 50 um to 500 um, and a thickness of the third resin film RF3 can be 50 um to 500 um.

The display device 1000 includes the first resin film RF1, the second resin film RF2, and the third resin film RF3 formed of the same material, as the lower substrate, the upper substrate, and the cover member. As described above, each of the first resin film RF1, the second resin film RF2, and the third resin film RF3 has an adhesive characteristic to bond layers disposed above and/or below the resin film. In the display device of the related art, each of the lower substrate, the upper substrate, and the cover member is bonded to a layer disposed above and/or below each of the lower substrate, the upper substrate, and the cover member by the adhesive layer. In contrast, in the display device 1000 of the present disclosure, each of the first resin film RF1, the second resin film RF2, and the third resin film RF3 serves as a substrate and has an adhesive characteristic so that the adhesive layer can be omitted. Therefore, a display device 1000 with a simple structure and a reduced thickness can be provided and the process is easy.

Further, when a separate adhesive layer is provided, a material of each of the lower substrate, the upper substrate, and the cover member is different from a material of the adhesive layer so that the stretching characteristic does not match so that the adhesive layer is reversely separated during the stretching. However, the display device 1000 according to the example embodiment of the present disclosure includes the first resin film RF1, the second resin film RF2, and the third resin film RF3 which simultaneously serve as the base material and the adhesive layer so that the problem of the reverse separation due to the non-matched stretching characteristic in the related art can be solved. By doing this, the display device 1000 with excellent stretching durability and reliability can be provided.

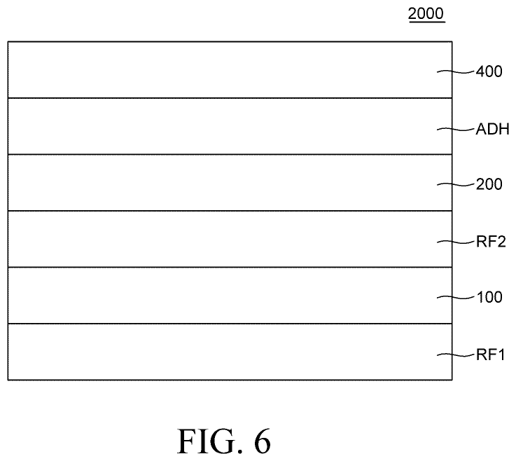

Hereinafter, various example embodiments of a display device including a resin film will be described with reference to FIGS. 6 to 8 according to the present disclosure.

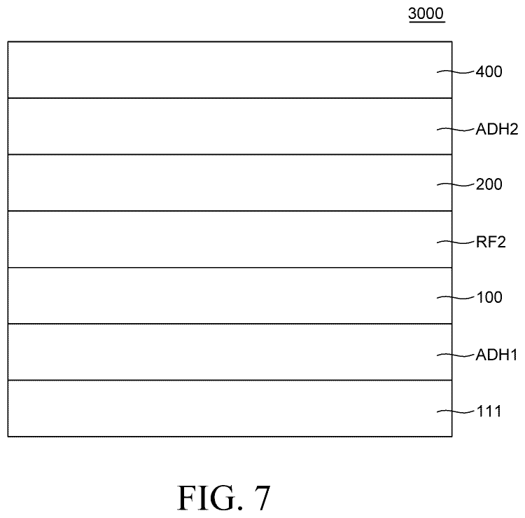

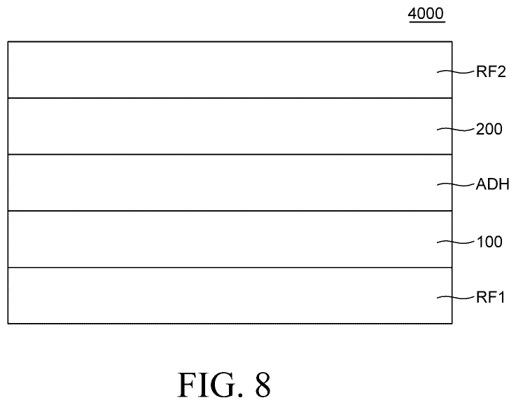

FIG. 6 is a schematic cross-sectional view for explaining another example of a display device according to an embodiment of the present disclosure. FIG. 7 is a schematic cross-sectional view for explaining still another example of a display device according to an embodiment of the present disclosure. FIG. 8 is a schematic cross-sectional view for explaining still another example of a display device according to an embodiment of the present disclosure.

When the display device illustrated in FIGS. 6 to 8 is described, the overlapping component with those described with reference to FIGS. 1 to 4 and 5A to 5J has the same characteristic so that a redundant description will be omitted or may be briefly provided. Further, display devices of FIGS. 6 to 8 can further include a plate assembly and a functional layer.

Referring to FIG. 6, according to an example embodiment of the present disclosure, a display device 2000 includes a first resin film RF1, a display panel 100, a second resin film RF2, a touch panel 200, an adhesive layer ADH, and a cover member 400. A redundant description for remaining components excluding the adhesive layer ADH and the cover member 400 is omitted. The display device 2000 illustrated in FIG. 6 does not include a third resin film as compared with the display device 1000 illustrated in FIGS. 1 to 4 and 5A to 5J, but include the cover member 400 and the adhesive layer ADH.

The cover member 400 is disposed above the touch panel 200. The cover member 400 covers and protects the touch panel 200 and the display panel 100. The cover member 400 can include a silicon rubber, such as polydimethylsiloxane (PDMS) or an elastomer such as polyurethane (PU) or polytetrafluoroethylene (PTFE).

The third resin film which is used as the cover member as described above has an adhesive characteristic but the cover member 400 formed of urethane and/or silicon has a high releasing strength. Therefore, in order to stably bond the cover member 400 and the touch panel 200, the adhesive layer ADH can be disposed between the cover member 400 and the touch panel 200. The adhesive layer ADH can be an optically clear adhesive (OCA) and can be configured by at least one of an acrylic adhesive, a silicon-based adhesive, and a urethane-based adhesive.

When the cover member 400 is bonded onto the touch panel 200 by means of the adhesive layer ADH as described above, in order to ensure the stretching durability, the stretching characteristics of the cover member 400 and the adhesive layer ADH can match. Therefore, a modulus of elasticity of the cover member 400 can be 7 MPa or lower and a thickness thereof can be 50 um to 300 um.

FIG. 7 is a schematic cross-sectional view for explaining still another example of a display device.

Referring to FIG. 7, a display device 3000 includes a lower substrate 111, an adhesive layer ADH1, a display panel 100, a resin film RF2, a touch panel 200, an adhesive layer ADH2, and a cover member 400. The display panel 100, the touch panel 200, the adhesive layer ADH2, and the cover member 400 of the display device 3000 are the same as described in FIGS. 1 to 6 and the resin film RF2 of the display device 3000 is the same as the second resin film RF2 which has been described above so that a redundant description will be omitted.

The lower substrate 111 supports and protects components of the display panel 100, below the display panel 100.

The lower substrate 111 which is a flexible substrate can include an insulating material which is bendable or stretchable. The lower substrate 111 can include a material which responds to the stretching of the display device 3000. For example, the lower substrate 111 and the upper substrate 112 can be formed of a silicon rubber, such as polydimethylsiloxane (PDMS), and an elastomer such as polyurethane (PU) or polytetrafluoroethylene (PTFE), respectively.

The lower substrate 111 formed of this material has a releasing strength higher than that of the first resin film which has been described above. Therefore, in order to bond the lower substrate 111 and the display panel 100, the adhesive layer ADH1 can be disposed between the lower substrate 111 and the display panel 100. The adhesive layer ADH1 can be an optically clear adhesive (OCA) and can be configured by at least one of an acrylic adhesive, a silicon-based adhesive, and a urethane-based adhesive.

A modulus of elasticity of the lower substrate 111 in the display device 3000 can be 1 MPa or lower and a thickness can be 25 um to 150 um. In this case, the stretching durability and the reliability are superior due to the stretching characteristic of the display device 3000.

FIG. 8 is a schematic cross-sectional view for explaining still another example of a display device according to embodiments of the present disclosure.

Referring to FIG. 8, according to an example embodiment of the present disclosure, a display device 4000 includes a first resin film RF1, a display panel 100, an adhesive layer ADH, a touch panel 200, and a second resin film RF2. Here, the display panel 100 and the touch panel 200 are the same as those described above so that a redundant description will be omitted.

The first resin film RF1 is disposed below the display panel 100 to support and protect components of the display panel 100. As described above, the first resin film RF1 can serve as a lower substrate and also have an adhesive characteristic. Therefore, the first resin film RF1 can be disposed to be in direct contact with the lower portion of the display panel 100 without an adhesive layer.

The second resin film RF2 is disposed above the touch panel 200. The second resin film RF2 supports and covers the components of the touch panel 200. In the display device 4000, the second resin film RF2 covers and protects the display panel 100 and the touch panel 200 to serve as the cover member.

The second resin film RF2 has an adhesive characteristic. Therefore, the second resin film RF2 can be disposed to be in direct contact with the upper portion of the touch panel 200 without an adhesive layer.

The display device 4000 can be manufactured by placing the display panel 100 on the first resin film RF1, placing the touch panel 200 on the second resin film RF2, and then bonding the display panel 100 and the touch panel 200 to be opposite to each other by means of the adhesive layer ADH. Therefore, the adhesive layer ADH is disposed between the touch panel 200 and the display panel 100 to bond the touch panel 200 and the display panel 100.

Materials which configure the first resin film RF1 and the second resin film RF2 in the display device 4000 are the same as those described above so that a redundant description will be omitted.

In the display device 4000, a modulus of elasticity of each of the first resin film RF1 and the second resin film RF2 can be 7 MPa or lower and a thickness can be 50 um to 800 um.

As described above, according to the example embodiments of the present disclosure, the display device includes a flexible resin film in at least one of locations, such as below the display panel, between the display panel and the touch panel, and above the touch panel. The resin film can include urethane acrylate and two types of photoinitiators having different absorption wavelengths. Such a resin film serves as a substrate which supports and protects components disposed above and/or below the resin film and has an adhesive characteristic. Therefore, when the resin film is provided, an adhesive layer for bonding the components disposed above and/or below the resin film is omitted so that the structure and the manufacturing process of the display device will be simplified.

Further, in a related art, an adhesive layer was used to bond the lower substrate, the upper substrate, and/or the cover member. However, in the related art case, there was a problem/limitation in that materials which configured the lower substrate, the upper substrate, the cover member, and the adhesive layer had a physical property different from a demanded physical property so that it was necessary to match the stretching characteristic. Further, in the related art, when a substrate formed of a silicon-based elastic material and a silicon-based adhesive layer are bonded, the adhesive strength therebetween is excellent, but the releasing strength of the silicon-based adhesive layer is high, so the adhesive strength between the silicon-based adhesive layer and the display panel is inferior, making it difficult to manufacture a display panel and the interfacial separation can occur as a result. Further in the related art, when the acrylic adhesive layer is bonded onto a substrate formed of a silicon-based elastic material, a surface energy difference between two materials is so big due to the material characteristic of the silicon-based elastic material and the acrylic adhesive layer, which causes the interfacial separation or the Z-axis deformation of a wiring line which configures a panel.

In contrast, according to one or more embodiment of the present disclosure, a resin film serves as a substrate and has an adhesive characteristic so that there is no need to bond the adhesive layer. Further, according to aspects of the present disclosure, the resin film has excellent stretching characteristic and excellent stretching durability and reliability as compared with the substrate bonded with the adhesive layer. Furthermore, according to aspects of the present disclosure, the adhesive layer is omitted to reduce the thickness of the display device, thereby reducing a stretching stress and implementing a highly stretchable display device.

Hereinafter, the effects of the present disclosure which have been described above will be described with reference to Example Embodiments. However, the following Example Embodiments are set forth to illustrate the present disclosure, but the scope of the present disclosure is not limited thereto. The term “Example Embodiment” refers to one or more examples/embodiments of the present disclosure.

### Example Embodiment 1

A specimen with a structure in which a first resin film having a modulus of elasticity of 3.7 MPa and a thickness of 100 um to 800 um, an LED display panel, a second resin film having a modulus of elasticity of 3.7 MPa and a thickness of 50 um to 500 um, a touch panel, and a third resin film having a modulus of elasticity of 3.7 MPa and a thickness of 50 um to 500 um were sequentially laminated was prepared.

At this time, each of the first resin film, the second resin film and the third resin film was manufactured by primarily curing (an intensity of UV was 1000 mW/cm² and a dose of UV light was 5000 mJ/cm²) a composition including urethane acrylate, a first photoinitiator with an absorption wavelength of 405 nm and a second photoinitiator with an absorption wavelength of 365 nm and then secondarily curing (an intensity of UV was 1000 mW/cm² and a dose of UV light was 10000 mJ/cm²) the composition.

### Example Embodiment 2

A specimen with the same structure as Example Embodiment 1 excluding that a modulus of elasticity of each of the first resin film, the second resin film, and the third resin film was changed to 4.4 MPa was manufactured by the same method.

### Comparative Embodiment 1

A specimen with a structure in which a lower substrate formed of PDMS with a modulus of elasticity of 0.8 MPa and a thickness of 300 um to 350 um, an acrylic adhesive layer (4×10⁴ Pa/Creep 127) with a thickness of 75 um to 150 um, an LED display panel, an acrylic adhesive layer (4×10⁴ Pa/Creep 127) with a thickness of 100 um, an upper substrate formed of PDMS with a modulus of elasticity of 0.8 MPa and a thickness of 300 um to 350 um, an acrylic adhesive layer (4×10⁴ Pa/Creep 127) with a thickness of 100 um, a touch panel, an acrylic adhesive layer (4×10⁴ Pa/Creep 127) with a thickness of 100 um, and an urethane or silicon cover film with a modulus of elasticity of 0.8 MPa and a thickness of 300 um were sequentially laminated was manufactured.

### Comparative Embodiment 2

A specimen with a structure in which a lower substrate formed of PDMS with a modulus of elasticity of 0.8 MPa and a thickness of 300 um to 350 um, a silicon-based adhesive layer (4.5×10⁴ Pa/Creep 39) with a thickness of 75 um to 150 um, an LED display panel, a silicon-based adhesive layer (4.5×10⁴ Pa/Creep 39) with a thickness of 100 um, an upper substrate formed of PDMS with a modulus of elasticity of 0.8 MPa and a thickness of 300 um to 350 um, a silicon-based adhesive layer (4.5×10⁴ Pa/Creep 39) with a thickness of 100 um, a touch panel, a silicon-based adhesive layer (4.5×10⁴ Pa/Creep 39) with a thickness of 100 um, and an urethane or silicon cover film with a modulus of elasticity of 0.8 MPa and a thickness of 300 um were sequentially laminated was manufactured.

### Comparative Embodiment 3

A specimen with a structure in which a lower substrate formed of PDMS with a modulus of elasticity of 0.8 MPa and a thickness of 300 um to 350 um, an acrylic adhesive layer (7×10⁴ Pa/Creep 43) with a thickness of 75 um to 150 um, an LED display panel, an acrylic adhesive layer (7×10⁴ Pa/Creep 43) with a thickness of 100 um, an upper substrate formed of PDMS with a modulus of elasticity of 0.8 MPa and a thickness of 300 um to 350 um, an acrylic adhesive layer (7×10⁴ Pa/Creep 43) with a thickness of 100 um, a touch panel, an acrylic adhesive layer (7×10⁴ Pa/Creep 43) with a thickness of 100 um, and an urethane or silicon cover film with a modulus of elasticity of 0.8 MPa and a thickness of 300 um were sequentially laminated was manufactured.

### Comparative Embodiment 4

A specimen with a structure in which a lower substrate formed of PDMS with a modulus of elasticity of 0.8 MPa and a thickness of 300 um to 350 um, an acrylic adhesive layer (1×10⁵ Pa/Creep 15) with a thickness of 75 um to 150 um, an LED display panel, an acrylic adhesive layer (1×10⁵ Pa/Creep 15) with a thickness of 100 um, an upper substrate formed of PDMS with a modulus of elasticity of 0.8 MPa and a thickness of 300 um to 350 um, an acrylic adhesive layer (1×10⁵ Pa/Creep 15) with a thickness of 100 um, a touch panel, an acrylic adhesive layer (1×10⁵ Pa/Creep 15) with a thickness of 100 um, and an urethane or silicon cover film with a modulus of elasticity of 0.8 MPa and a thickness of 300 um were sequentially laminated was manufactured.

### Experimental Embodiment

A manufacturing performance and a stretching characteristic for a specimen of each of Example Embodiments 1 and 2 and Comparative Embodiments 1 to 4 were evaluated. In addition, a releasing strength and an adhesive strength of a bonded product of the PDMS substrate and the adhesive layer of Comparative Embodiments 1 to 4 were evaluated. The results were represented in the following Table 1.

TABLE 1

| | Example Embodiment | | Comparative Embodiment | | | |
|---|---|---|---|---|---|---|
| | 1 | 2 | 1 | 2 | 3 | 4 |
| Releasing | — | — | 24 | <10 | <10 | 26 |
| strength | | | gf/ | gf/ | gf/ | gf/ |
| | | | inch | inch | inch | inch |
| Adhesive | | | 1.6 | 0.4 | 1.2 | 1.5 |
| strength | | | kgf/ | kgf/ | kgf/ | kgf/ |
| | | | inch | inch | inch | inch |
| Manufacturing | ◯ | ◯ | X | ◯ | ◯ | ◯ |
| performance | | | | | | |
| Stretching | ◯ | ◯ | ◯ | X | X | X |
| characteristic | (800%) | (550%) | | | | |

Referring to Table 1, it was confirmed that in the display device of each of Example Embodiments 1 and 2 including the first resin film, the second resin film, and the third resin film, a defect such as a Z-axis deformation of the panel line did not occur and the surface was flat so that the manufacturing performance was excellent. When the evaluation results of the stretching characteristics of Example Embodiments 1 and 2 were compared, it was confirmed that a ductile breaking rate of the display device of Example Embodiment 1 was 800% or higher and a ductile breaking rate of the display device of Example Embodiment 2 was 550%. For example, it is understood that the stretching characteristic of the display device including a resin film having a lower modulus of elasticity is superior.

In the meantime, Comparative Embodiment 1 had excellent releasing characteristic, adhesive characteristic, and stretching characteristic, but in evaluation of the manufacturing performance, the surface of the display device was not uniform and minute wrinkles were observed. Further, in Comparative Embodiment 2, it was confirmed that an adhesive strength of the adhesive layer was inferior to be 0.4 kgf/inch, which resulted in the interfacial separation in the evaluation of stretching characteristic. Further, in the case of Comparative Embodiment 3, a result of evaluating the adhesive characteristic, the releasing characteristic, and the manufacturing performance was excellent, but it was confirmed that a line disconnection was caused due to the deformation of the specimen, in the stretching characteristic evaluation. Further, in Comparative Embodiment 4, it was confirmed that the releasing strength was high and the line disconnection occurred in the stretching characteristic evaluation.

In addition, a high temperature/high humidity reliability evaluation was performed on the resin film used for Example Embodiment 1. The high temperature/high humidity evaluation was performed by change in transmittance with the passage of time while storing the specimen for 3000 hours under three conditions of 60° C., 80° C., and 60° C./relative humidity of 90%. As an evaluation result, it was confirmed that in the resin film according to the example embodiments of the present disclosure, the transmittance was rarely changed under the high temperature and/or high humidity condition.

The example embodiments of the present disclosure can also be described as follows:

According to an aspect of the present disclosure, a display device includes a display panel including a pattern layer which includes a plurality of first plate patterns which are spaced apart from each other and in which a sub pixel including a display element and a driving element is disposed; a plurality of first line patterns connecting the plurality of first plate patterns; a plurality of second plate patterns which are spaced apart from each other and in which a gate driver is disposed; and a plurality of second line patterns connecting the plurality of second plate patterns or connecting the first plate pattern and the second plate pattern, and a resin film that is flexible and disposed in at least one location below or above the display panel. The resin film is obtained by curing a material including urethane acrylate and two types of photoinitiators.

The two types of photoinitiators can include a first photoinitiator having an absorption wavelength of 400 nm or higher and a second photoinitiator having an absorption wavelength of 370 nm or lower.

A modulus of elasticity of the resin film can be 7 MPa or lower and a ductile breaking rate of the resin film can be 400% or higher.

The display device can further include a touch panel on the display panel. The resin film can be disposed in at least one location below the display panel, between the display panel and the touch panel, or above the touch panel.

The resin film can be disposed between the display panel and the touch panel to bond the display panel and the touch panel.

A modulus of elasticity of the resin film can be 3 MPa to 5 MPa and a thickness of the resin film can be 50 um to 500 um.

The display device can further include a lower substrate bonded to a bottom of the display panel by an adhesive layer; and a cover member bonded to a top of the touch panel by the adhesive layer.

Each of the lower substrate and the cover member can include at least one of urethane and silicon, a modulus of elasticity of the lower substrate can be 1 MPa or lower and a thickness of the lower substrate can be 25 um to 150 um, and a modulus of elasticity of the cover member can be 7 MPa or lower and a thickness of the cover member can be 50 um to 300 um.

The resin film can include a first resin film which supports the pattern layer below the display panel; and a second resin film between the display panel and the touch panel so as to bond the display panel and the touch panel.

A modulus of elasticity of the first resin film can be 3 MPa to 5 MPa and a thickness of the first resin film can be 100 um to 800 um and a modulus of elasticity of the second resin film can be 3 MPa to 5 MPa and a thickness of the second resin film can be 50 um to 500 um.

The display device can further include a cover member which is bonded to a top of the touch panel by an adhesive layer. The cover member can include at least one of urethane and silicon and a modulus of elasticity of the cover member can be 7 MPa or lower and a thickness of the cover member can be 50 um to 300 um.

The resin film can further include a third resin film on the touch panel so as to be in direct contact with the touch panel.

A modulus of elasticity of the third resin film can be 3 MPa to 5 MPa and a thickness of the third resin film can be 50 um to 500 um.

The resin film can include a first resin film which supports the pattern layer below the display panel; and a second resin film on the touch panel so as to be in direct contact with an upper portion of the touch panel. The touch panel and the display panel can be bonded by an adhesive layer.

A modulus of elasticity of the first resin film can be 7 MPa or lower and a thickness of the first resin film can be 50 um to 800 um and a modulus of elasticity of the second resin film can be 7 MPa or lower and a thickness of the second resin film can be 50 um to 800 um.

The adhesive layer can be an optically clear adhesive (OCA) and can be configured by an acrylic adhesive, a silicon-based adhesive, and a urethane-based adhesive.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display panel including a pattern layer which includes:
a plurality of first plate patterns which are spaced apart from each other and in which a sub pixel including a display element and a driving element is disposed;
a plurality of first line patterns connecting the plurality of first plate patterns;
a plurality of second plate patterns which are spaced apart from each other and in which a gate driver is disposed; and
a plurality of second line patterns connecting the plurality of second plate patterns or connecting one of the plurality of first plate patterns and one of the plurality of second plate patterns; and
a resin film that is flexible and disposed in at least one location below or above the display panel,
wherein the resin film includes a material having urethane acrylate and two types of photoinitiators, which has been cured.

2. The display device according to claim 1, wherein the two types of photoinitiators include:
a first photoinitiator having an absorption wavelength of 400 nm or higher, and
a second photoinitiator having an absorption wavelength of 370 nm or lower.

3. The display device according to claim 1, wherein a modulus of elasticity of the resin film is 7 MPa or lower, and a ductile breaking rate of the resin film is 400% or higher.

4. The display device according to claim 1, further comprising:
a touch panel above the display panel,
wherein the resin film is disposed in at least one location below the display panel, between the display panel and the touch panel, or above the touch panel.

5. The display device according to claim 4, wherein the resin film is disposed between the display panel and the touch panel to bond the display panel and the touch panel.

6. The display device according to claim 5, wherein a modulus of elasticity of the resin film is 3 MPa to 5 MPa, and a thickness of the resin film is 50 um to 500 um.

7. The display device according to claim 5, further comprising:
a lower substrate bonded to a bottom of the display panel by an adhesive layer; and
a cover member bonded to a top of the touch panel by the adhesive layer.

8. The display device according to claim 7, wherein each of the lower substrate and the cover member includes at least one of urethane and silicon,
wherein a modulus of elasticity of the lower substrate is 1 MPa or lower, and a thickness of the lower substrate is 25 um to 150 um, and
wherein a modulus of elasticity of the cover member is 7 MPa or lower, and a thickness of the cover member is 50 um to 300 um.

9. The display device according to claim 4, wherein the resin film includes:
a first resin film which supports the pattern layer below the display panel; and
a second resin film between the display panel and the touch panel so as to bond the display panel and the touch panel.

10. The display device according to claim 9, wherein a modulus of elasticity of the first resin film is 3 MPa to 5 MPa, and a thickness of the first resin film is 100 um to 800 um, and
wherein a modulus of elasticity of the second resin film is 3 MPa to 5 MPa, and a thickness of the second resin film is 50 um to 500 um.

11. The display device according to claim 10, further comprising:
a cover member which is bonded to a top of the touch panel by an adhesive layer,
wherein the cover member includes at least one of urethane and silicon, and
wherein a modulus of elasticity of the cover member is 7 MPa or lower, and a thickness of the cover member is 50 um to 300 um.

12. The display device according to claim 10, wherein the resin film further includes:
a third resin film above the touch panel so as to be in direct contact with the touch panel.

13. The display device according to claim 12, wherein a modulus of elasticity of the third resin film is 3 MPa to 5 MPa, and a thickness of the third resin film is 50 um to 500 um.

14. The display device according to claim 4, wherein the resin film includes:
a first resin film which supports the pattern layer below the display panel; and
a second resin film above the touch panel so as to be in direct contact with an upper portion of the touch panel, and
wherein the touch panel and the display panel are bonded by an adhesive layer.

15. The display device according to claim 14, wherein a modulus of elasticity of the first resin film is 7 MPa or lower, and a thickness of the first resin film is 50 um to 800 um, and
wherein a modulus of elasticity of the second resin film is 7 MPa or lower, and a thickness of the second resin film is 50 um to 800 um.

16. The display device according to claim 7, wherein the adhesive layer is an optically clear adhesive (OCA) and is configured by at least one of an acrylic adhesive, a silicon-based adhesive, and a urethane-based adhesive.

17. The display device according to claim 11, wherein the adhesive layer is an optically clear adhesive (OCA) and is configured by at least one of an acrylic adhesive, a silicon-based adhesive, and a urethane-based adhesive.

18. The display device according to claim 14, wherein the adhesive layer is an optically clear adhesive (OCA) and is configured by at least one of an acrylic adhesive, a silicon-based adhesive, and a urethane-based adhesive.
